(19) United States
(12) Patent Application Publication
(10) Pub. No.: US 2024/0312880 A1
(43) Pub. Date: Sep. 19, 2024

(54) SEMICONDUCTOR DEVICE, METHOD OF MANUFACTURING THE SAME, AND POWER CONVERSION DEVICE

(71) Applicant: Mitsubishi Electric Corporation, Tokyo (JP)

(72) Inventors: Yusuke KUSAKABE, Tokyo (JP); Yoshihisa UCHIDA, Tokyo (JP); Tatsunori YANAGIMOTO, Tokyo (JP); Kazutaka IKEDA, Tokyo (JP)

(73) Assignee: Mitsubishi Electric Corporation, Tokyo (JP)

(21) Appl. No.: 18/539,036

(22) Filed: Dec. 13, 2023

(30) Foreign Application Priority Data
Mar. 14, 2023 (JP) 2023-039512

(51) Int. Cl. H01L 23/495; H01L 23/00; H01L 23/053

(52) U.S. Cl. CPC H01L 23/49544; H01L 23/053; H01L 24/37; H01L 24/40; H01L 24/84; H01L 2224/37005; H01L 2224/40225; H01L 2224/40491; H01L 2224/84007; H01L 2224/84897

(57) ABSTRACT

Provided is a semiconductor device having a structure of directly bonding a lead electrode to a semiconductor element through a bonding layer, in which whether the bonding layer has a predetermined thickness can be checked through a visual inspection. The semiconductor device includes: a semiconductor element mounted on an insulating substrate or a lead frame; a bonding layer on the semiconductor element; and a lead electrode including a main body plate electrically connected to an external electrode, and a cantilevered plate having one end being connected to the main body plate as a connection part, and being cut from the main body plate, wherein the cantilevered plate is bent in a direction of the semiconductor element with respect to the main body plate, and has an other end embedded in the bonding layer, and the bonding layer covers at least a part of an upper surface of the cantilevered plate.

### BACKGROUND OF THE INVENTION

### Field of the Invention

The present disclosure relates to a semiconductor device, a method of manufacturing the same, and a power conversion device.

### Description of the Background Art

A technology of directly bonding a lead electrode to a semiconductor element through a bonding layer without connecting the lead electrode to the semiconductor element through a metal wire is known as a technology for pursuing a larger current, longer life, and higher reliability in semiconductor devices to be used for, for example, power conversion devices. In a semiconductor device with a structure of directly bonding a lead electrode to a semiconductor element through a bonding layer, for example, the lead electrode and the semiconductor element are made of materials different in thermal expansion coefficient. Thus, the stress caused by the difference in thermal expansion coefficient is added to the bonding layer. Thus, a certain thickness of the bonding layer and prevention of voids, etc., are crucial to prevent the bonding layer from peeling off. For example, Japanese Patent Application Laid-Open No. S63-090160 discloses forming a hole on a bonding surface of a lead electrode to enable the gas generated when solder is molten to escape outside as one of the conventional technologies.

Although the conventional technology described in the aforementioned document allows one to visually check the bonding layer from the hole formed on the bonding surface of the lead electrode, the technology does not allow one to check the thickness of the bonding layer actually formed. Thus, the problem is that whether the bonding layer has a predetermined thickness cannot be checked through a visual inspection.

### SUMMARY

The present disclosure has been conceived to solve the problem, and has an object of providing a semiconductor device which has a structure of directly bonding a lead electrode to a semiconductor element through a bonding layer and in which whether the bonding layer has a predetermined thickness can be checked through a visual inspection.

A semiconductor device according to the present disclosure includes: a semiconductor element mounted on an insulating substrate or a lead frame; a bonding layer formed on the semiconductor element; and a lead electrode including a main body plate electrically connected to an external electrode, and a cantilevered plate with one end being connected to the main body plate as a connection part, the cantilevered plate being cut from the main body plate, wherein the cantilevered plate is bent in a direction of the semiconductor element with respect to the main body plate, and has an other end embedded in the bonding layer, and the bonding layer covers at least a part of an upper surface of the cantilevered plate.

Thus, it is possible to obtain a semiconductor device which has a structure of directly bonding a lead electrode to a semiconductor element through a bonding layer and in which whether the bonding layer has a predetermined thickness can be checked through a visual inspection.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of a semiconductor device 10 according to Embodiment 1;

FIG. 2 is an excerpted top view of an area of a lead electrode in the semiconductor device 10 according to Embodiment 1;

FIG. 3 is a schematic cross-sectional view of a semiconductor device 20 according to Modification 1 of Embodiment 1;

FIG. 4 is an excerpted top view of the semiconductor device 20 illustrating an area including a lead electrode according to Modification 2 of Embodiment 1;

FIG. 5 is a schematic cross-sectional view of a semiconductor device 30 according to Embodiment 2;

FIG. 6 is a schematic cross-sectional view when a lead electrode 41 is placed apart from a semiconductor element 15 in a semiconductor device to which a conventional technology has been applied;

FIG. 7 is a schematic cross-sectional view when a lead electrode 31 is placed apart from the semiconductor element 15 in the semiconductor device according to Embodiment 2;

FIG. 8A is a perspective view illustrating an example structure of a cantilevered plate according to Embodiment 3;

FIG. 8B is a perspective view illustrating an example structure of a cantilevered plate according to Embodiment 3; and

FIG. 8C is a perspective view illustrating an example structure of a cantilevered plate according to Embodiment 3.

### DESCRIPTION OF THE PREFERRED EMBODIMENTS

The following will describe example semiconductor devices according to the present disclosure. The semiconductor devices are not restricted by Embodiments below, but can be arbitrarily modified and implemented without departing from the spirit and scope of the present disclosure.

### Embodiment 1

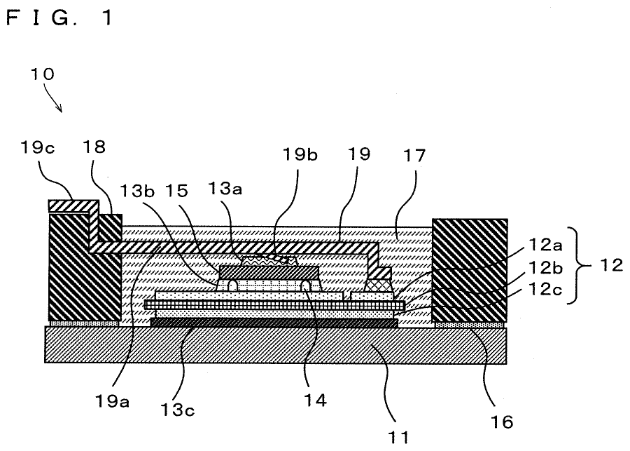

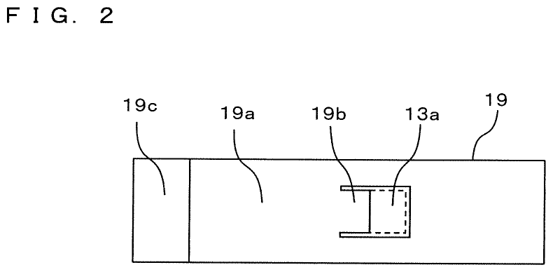

FIG. 1 is a schematic cross-sectional view of a semiconductor device 10 according to Embodiment 1. FIG. 2 is an excerpted top view of an area of a lead electrode 19 in the semiconductor device 10. First, the semiconductor device 10 includes a base plate 11, an insulating substrate 12, bonding layers 13a, 13b, and 13c, bumps 14, a semiconductor element 15, an adhesive 16, a sealant 17, a casing 18, a lead electrode 19, and an external electrode 19c as illustrated in FIG. 1. A specific structure of the semiconductor device 10 will be hereinafter described, assuming a direction of a surface of the base plate 11 to which the insulating substrate 12 is bonded to be up and a direction of a surface of the base plate 11 to which the insulating substrate 12 is not bonded to be down.

In the semiconductor device 10, the insulating substrate 12 is bonded to the base plate 11 through the bonding layer 13c. The insulating substrate 12 is obtained by forming a circuit pattern 12c on a lower surface of an insulating layer 12b and forming a circuit pattern 12a on an upper surface of the insulating layer 12b. The bumps 14 are formed on an upper surface of the insulating substrate 12. The semiconductor element 15 disposed through the bumps 14 is bonded to the insulating substrate 12 through the bonding layer 13b. The lead electrode 19 is bonded to the semiconductor element 15 through the bonding layer 13a. A cantilevered plate 19b of the lead electrode 19 is bent in a direction of the semiconductor element 15 and buried in the bonding layer 13a. At least a part of an upper surface of the cantilevered plate 19b is covered with the bonding layer 13a. Here, the upper surface of the cantilevered plate 19b is a surface opposite to the surface of the cantilevered plate 19b which faces the semiconductor element 15. Thus, the lower surface of the cantilevered plate 19b is the surface of the cantilevered plate 19b which faces the semiconductor element 15. Furthermore, the casing 18 housing the semiconductor element 15 is disposed. The casing 18 is bonded to the base plate 11 through the adhesive 16. The casing 18 supports the external electrode 19c electrically connected to the lead electrode 19. The semiconductor element 15 housed in the casing 18 is sealed by the sealant 17.

The base plate 11 is preferably made of a material with superior thermal conductivity, specifically, aluminum (Al) or copper (Cu). The insulating layer 12b is suitably made of an insulator with superior thermal conductivity. The insulator contains a ceramic or a resin. Specific examples of the insulator include aluminum nitride (AlN) and silicon nitride (Si₃N₄). The circuit pattern 12a on the upper surface of the insulating layer 12b and the circuit pattern 12c on the lower surface of the insulating layer 12b are made of, for example, aluminum (AI) or copper (Cu).

Furthermore, solder is applied as the bonding layers 13a, 13b, and 13c. The bumps 14 are made of, for example, aluminum (AI). Instead of solder, a paste material obtained by dispersing metal particles made of, for example, silver into an organic solvent may be applied as the bonding layers 13a, 13b, and 13c.

Examples of the semiconductor element 15 include a semiconductor element made of Si, and a semiconductor element made of a wide bandgap semiconductor with a band gap larger than that of Si. Specific examples of the wide bandgap semiconductor include silicon carbide (SiC), gallium nitride (GaN), and diamond (C). The type of the semiconductor element is not particularly restricted. For example, semiconductor elements such as an insulated-gate bipolar transistor (IGBT), a metal-oxide-semiconductor field-effect transistor (MOSFET), a reverse conducting IGBT (RC-IGBT) on which an IGBT and a diode are integrated as one semiconductor chip, and a high electron mobility transistor (HEMT) are applicable as the semiconductor element 15. FIG. 1 illustrates, for the sake of simplicity, a case where the number of semiconductor elements mounted on the insulating substrate 12 is only the single semiconductor element 15. The number of semiconductor elements is not limited to one but a necessary number of semiconductor elements of a necessary kind may be mounted on the insulating substrate 12 according to the usage.

Representative examples of the adhesive 16 include silicone-based and epoxy-based adhesives.

Preferably, the sealant 17 has a modulus of elasticity allowing to ensure intimate contact with, for example, the semiconductor element 15 and the lead electrode 19 housed in the casing 18, and has a heat resistance temperature allowing to ensure the reliability. The sealant 17 preferably has, for example, a modulus of elasticity approximately lower than or equal to 200 mPa-s and a heat resistance temperature approximately higher than or equal to 150° C. Specific examples of a material of the sealant 17 include, but not limited to, silicone gel and an epoxy resin.

The casing 18 is made of a resin with a softening temperature with which the casing 18 is not thermally deformed in a use temperature range of semiconductor devices, and has insulating properties. Specific examples of a material of the casing 18 include, but not limited to, poly phenylene sulfide (PPS) with a softening temperature higher than or equal to 280° C.

The lead electrode 19 includes a main body plate 19a and the cantilevered plate 19b. The lead electrode 19 is a flat plate with a thickness approximately larger than or equal to 0.5 mm and smaller than or equal to 2.0 mm, and is made of, for example, Cu or a material containing Cu. Although FIG. 1 illustrates the lead electrode 19 integrally formed with the external electrode 19c as one electrode, the lead electrode 19 should be electrically connected to the external electrode 19c. The lead electrode 19 and the external electrode 19c that are separately formed may be not only connected to each other through solder, welding, or ultrasonic bonding but also electrically connected to each other through a circuit pattern in the semiconductor device. As illustrated in FIGS. 1 and 2, the lead electrode 19 includes the main body plate 19a electrically connected to the external electrode 19c, and the cantilevered plate 19b cut from the main body plate 19a with one end being connected to the main body plate 19a as a connection part. The cantilevered plate 19b is diagonally bent from the main body plate 19a in the direction of the semiconductor element 15, and has another end embedded in the bonding layer 13a. The cantilevered plate 19b is electrically connected to the semiconductor element 15 through the bonding layer 13a. Here, the bonding layer 13a has a thickness larger than or equal to that of the cantilevered plate 19b which is approximately larger than or equal to 0.5 mm and smaller than or equal to 10.0 mm. A part of the bonding layer 13a covers at least a part of an upper surface of the cantilevered plate 19b. When the bonding layer 13a has a desired thickness, for example, the thickness, the length, and the bending angle of the cantilevered plate 19b, and a distance between the lead electrode 19 and the semiconductor element 15 are designed so that the bonding layer 13a covers at least a part of the upper surface of the cantilevered plate 19b. A specification corresponding to each semiconductor device is applicable. In other words, a specification in which the bonding layer 13a covers at least a part of the upper surface of the cantilevered plate 19b when the bonding layer 13a has a predetermined thickness and a specification in which the bonding layer 13a does not cover the upper surface of the cantilevered plate 19b when the bonding layer 13a does not have the predetermined thickness are applicable. Put it differently, the semiconductor device 10 has a structure that allows one to check from the appearance whether the bonding layer 13a covers at least a part of the upper surface of the cantilevered plate 19b to check whether the bonding layer 13a has a predetermined thickness, without performing any non-destructive inspection by an inspection device using, for example, ultrasonic, X-rays, or laser. FIG. 2 illustrates, but not limited to, a case where the cantilevered plate 19b is rectangular with one side connected to the main body plate 19a as a fixed end and with the other three sides punched out and including an opposite side of the one side as a free end. As long as whether the bonding layer 13a covers at least apart of the upper surface of the cantilevered plate 19b can be determined, any shape including a trapezoid and a triangle is applicable to the cantilevered plate 19b.

Although the semiconductor element 15 is disposed on the insulating substrate 12 through the bumps 14 and the bonding layer 13b in FIG. 1, the semiconductor device 10 may have a structure without the bumps 14. A lead frame may replace the insulating substrate 12 on which the semiconductor element 15 is disposed, which will be described later in Modification 1 of Embodiment 1. FIG. 1 has an objective of describing the present disclosure, and thus omits, for example, signal lines, wires, and signal terminals for establishing electrical connections with the semiconductor element 15, etc., in the semiconductor device 10. The materials described above are representative examples. As long as the materials produce the advantages of the present disclosure, the materials are not limited to the representative examples.

Next, a method of manufacturing the semiconductor device 10 will be described. First, a lower surface of the insulating substrate 12 is bonded to the base plate 11 through the bonding layer 13c, and the upper surface of the insulating substrate 12 is bonded to the semiconductor element 15 through the bonding layer 13b as a semiconductor element bonding step. The bonding method is heating a bonding material contained in the bonding layers 13b and 13c to a temperature exceeding a melting point of the bonding material, so that the base plate 11, the insulating substrate 12, and the semiconductor element 15 are bonded through the bonding layers 13b and 13c. The bonding material for forming the bonding layers 13b and 13c may be, for example, plate solder molded in advance, or soldering paste to be applied using, for example, screen printing or a dispenser.

Next, the casing 18 is bonded to the base plate 11 through the adhesive 16 as a casing adhering step. This bonding may include processes of fastening the casing 18 to the base plate 11 using, for example, a clamp fixture and heating the adhesive 16 to be solidified. The casing 18 may be further fastened to the base plate 11 using, for example, tapping screws (not illustrated).

Next, the bonding layer 13a is formed on the semiconductor element 15 as a bonding layer formation step. Before the lead electrode 19 is disposed on the semiconductor element 15, the bonding layer 13a may be supplied on the semiconductor element 15 in dispense coating, screen printing, or another method. After the lead electrode 19 is disposed, the bonding layer 13a may be dispensed and supplied from the opening of the lead electrode 19 which is formed when the cantilevered plate 19b is formed. In other steps including the semiconductor element bonding step and the casing adhering step, solder may be caused to flow on the semiconductor element 15 in advance.

Next, the lead electrode 19 with the cantilevered plate 19b is bonded to the semiconductor element 15 through the bonding layer 13a as a direct bonding step. Here, the cantilevered plate 19b is already formed on the lead electrode 19 in advance by, for example, press working for the sake of simplicity. After the lead electrode 19 is disposed on the semiconductor element 15 through the bonding layer 13a, heating a bonding material contained in the bonding layer 13a to a temperature exceeding a melting point of the bonding material bonds the lead electrode 19 with the cantilevered plate 19b to the semiconductor element 15.

Next, whether the bonding layer 13a has a predetermined thickness is determined through a visual inspection of the cantilevered plate 19b exposed from the bonding layer 13a as a determination step. The determination method is checking through a visual inspection whether the bonding layer 13a covers at least a part of the upper surface of the cantilevered plate 19b to determine whether the bonding layer 13a has a predetermined thickness. Examples of the visual inspection method may include a method of making a determination by visual check using an optical microscope, and a method of making a determination using an image captured by a camera. The available visual inspection methods include a method of making an automatic determination through image recognition on a captured image by an automatic inspection device, etc., by comparing a predetermined pattern with the captured image, and a method of making an automatic determination by comparing a pattern learned from an AI technique with the captured image.

Next, electrical connections between the semiconductor element 15, the circuit pattern 12a, the circuit pattern 12c, and the other signal circuits (not illustrated) in the semiconductor device which are necessary for control are established as a connection step. Specifically, the electrical connections are established by, but not limited to, ultrasonic bonding wires made of, for example, aluminum (Al) or gold (Au).

Next, the sealant 17 seals the elements in the casing 18 as a sealing step. As described above, the sealant 17 is often made of, but not limited to, silicone gel or an epoxy resin. The sealant 17 may be any sealant with desired physical properties such as a heat resistance temperature, a thermal expansion coefficient, and a modulus of elasticity. A cure treatment for hardening the sealant 17 is performed as necessary. Consequently, the semiconductor device 10 can be manufactured. The electrical characteristic inspection, etc., during manufacturing processes and after the manufacturing can be arbitrarily added.

With application of the semiconductor device structured in such a manner, checking from the appearance whether the bonding layer 13a covers at least a part of the upper surface of the cantilevered plate 19b can determine whether the bonding layer 13a has a predetermined thickness.

The semiconductor device 10 according to Embodiment 1 includes: the semiconductor element 15 mounted on the insulating substrate 12 or a lead frame; the bonding layer 13a formed on the semiconductor element 15; and the lead electrode 19 including the main body plate 19a electrically connected to the external electrode 19c, and the cantilevered plate 19b with one end being connected to the main body plate 19a as a connection part, the cantilevered plate 19b being cut from the main body plate 19a, wherein the cantilevered plate 19b is bent in a direction of the semiconductor element 15 with respect to the main body plate 19a, and has an other end embedded in the bonding layer 13a, the bonding layer 13a having a thickness exceeding a predetermined thickness covers at least a part of an upper surface of the cantilevered plate 19b, and the bonding layer 13a having a thickness smaller than or equal to the predetermined thickness does not cover the upper surface of the cantilevered plate 19b.

This structure can obtain a semiconductor device which has a structure of directly bonding the lead electrode 19 to the semiconductor element 15 through the bonding layer 13a and in which whether the bonding layer 13a has a predetermined thickness can be checked through a visual inspection. Furthermore, application of the visual inspection can suppress an increase in the manufacturing cost more than that with application of a non-destructive inspection.

A method of manufacturing the semiconductor device 10 according to Embodiment 1 includes: the bonding layer formation step of forming the bonding layer 13a on the semiconductor element 15; the direct bonding step of embedding, into the bonding layer 13a, an other end of the cantilevered plate 19b with one end being connected to the main body plate 19a of the lead electrode 19 as a connection part to bond the other end to the semiconductor element 15, the other end being cut from the main body plate 19a; and a determination step of determining whether the bonding layer 13a has a predetermined thickness through a visual inspection of the cantilevered plate 19b exposed from the bonding layer 13a.

This structure can provide a method of manufacturing a semiconductor device which has a structure of directly bonding the lead electrode 19 to the semiconductor element 15 through the bonding layer 13a and in which whether the bonding layer 13a has a predetermined thickness can be checked through a visual inspection.

### Modification 1 of Embodiment 1

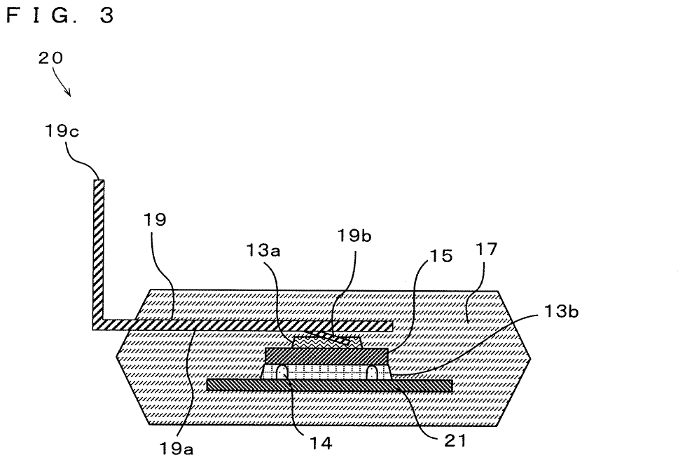

FIG. 3 is a schematic cross-sectional view of a semiconductor device 20 according to Modification 1 of Embodiment 1. As illustrated in FIG. 3, the semiconductor device 20 includes a lead frame 21, the bonding layers 13a and 13b, the bumps 14, the semiconductor element 15, the sealant 17, the lead electrode 19, and the external electrode 19c. A specific structure of the semiconductor device 20 will be hereinafter described, assuming a direction of a surface of the lead frame 21 to which the semiconductor element 15 is bonded to be up and a direction of a surface of the lead frame 21 to which the semiconductor element 15 is not bonded to be down. The semiconductor device 20 differs from the semiconductor device 10 according to Embodiment 1 in that the semiconductor device 20 adopts a lead frame package in which the semiconductor element 15 and the others are disposed on not an insulating substrate but the lead frame 21 and the sealant 17 seals the entirety of the semiconductor element 15 without a casing. The other structures of Modification 1 of Embodiment 1 are identical to those of Embodiment 1. In the semiconductor device 20, the semiconductor element 15 disposed through the bumps 14 is bonded to the lead frame 21 through the bonding layer 13b. The sealant 17 seals the semiconductor element 15, the lead electrode 19, and the lead frame 21. The external electrode 19c is exposed from the sealant 17. The other structures of Modification 1 of Embodiment 1 are identical to those of Embodiment 1. Although FIG. 3 illustrates a structure of the semiconductor device 20 in which the sealant 17 solely seals the back side of the lead frame 21 on which the semiconductor element 15 is not disposed, the semiconductor device 20 is not limited to this but may have a structure in which a heat spreader is mounted on the back side of the lead frame 21 through an insulation sheet. One of the surfaces of the lead frame 21 may have a circuit pattern.

With application of the semiconductor device even adopting the lead frame package, checking from the appearance whether the bonding layer 13a covers at least a part of the upper surface of the cantilevered plate 19b can determine whether the bonding layer 13a has a predetermined thickness.

As described above, the semiconductor device 20 according to Modification 1 of Embodiment 1 includes: the semiconductor element 15 disposed on the lead frame 21; the bonding layer 13a formed on the semiconductor element 15; and the lead electrode 19 bonded to the semiconductor element 15 through the bonding layer 13a and including the cantilevered plate 19b bent in a direction of the semiconductor element 15 and coming in contact with the bonding layer 13a, wherein the bonding layer 13a having a thickness exceeding a predetermined thickness covers at least a part of the upper surface of the cantilevered plate 19b, and the bonding layer 13a having a thickness smaller than or equal to the predetermined thickness does not sit on the upper surface of the cantilevered plate 19b.

This structure can obtain a semiconductor device which has a structure of directly bonding the lead electrode 19 to the semiconductor element 15 through the bonding layer 13a and in which whether the bonding layer 13a has a predetermined thickness can be checked through a visual inspection, similarly to Embodiment 1.

### Modification 2 of Embodiment 1

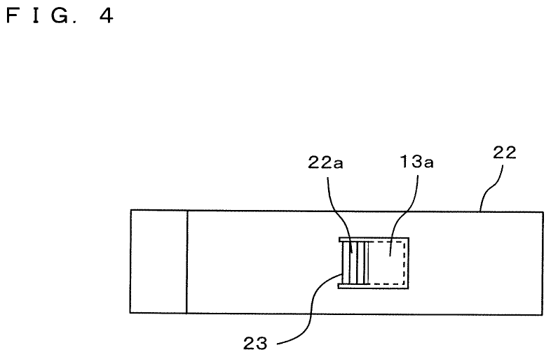

FIG. 4 is a top view of a lead electrode 22 according to Modification 2 of Embodiment 1. As illustrated in FIG. 4, a semiconductor device according to Modification 2 of Embodiment 1 differs from that according to Embodiment 1 in that a cantilevered plate 22a includes a scale 23 on the upper surface. The other structures of Modification 2 of Embodiment 1 are identical to those of Embodiment 1. Examples of a method of forming the scale 23 include stamping, ink printing, and laser marking. The method is not limited to these, but is arbitrarily applicable. FIG. 4 illustrates the scale 23 with equal intervals for the sake of simplicity. This can determine through a visual inspection not only whether the bonding layer 13a has a predetermined thickness but also, for example, whether the bonding layer 13a falls within a tolerance of the predetermined thickness. The other possible examples of the scale include a scale indicating an upper limit value and a lower limit value of the thickness that should accommodate the bonding layer 13a, and a scale with an individual reference line corresponding to the specification of each product. This can increase the inspection accuracy of the thickness of the bonding layer 13a through a visual inspection more than that without any scale.

As described above, the semiconductor device according to Modification 2 of Embodiment 1 is characterized in that the cantilevered plate 22a includes the scale 23 on the upper surface, in addition to the structure of the semiconductor device according to Embodiment 1.

This structure allows one to check the area of the upper surface of the cantilevered plate 22a covered by the bonding layer 13a using the scale 23 in a structure of directly bonding the lead electrode 22 to the semiconductor element 15 through the bonding layer 13a, in addition to the advantages of Embodiment 1. Thus, a semiconductor device in which whether the bonding layer 13a has a predetermined thickness can be checked through a visual inspection with high accuracy can be obtained.

### Embodiment 2

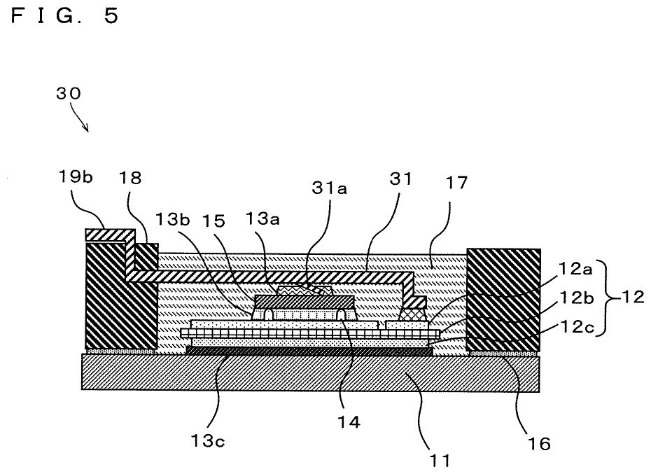

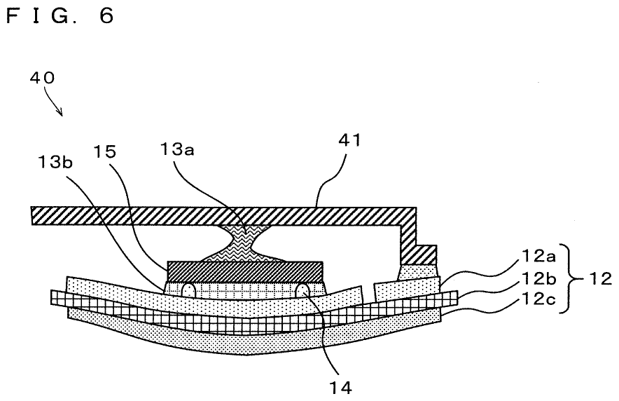

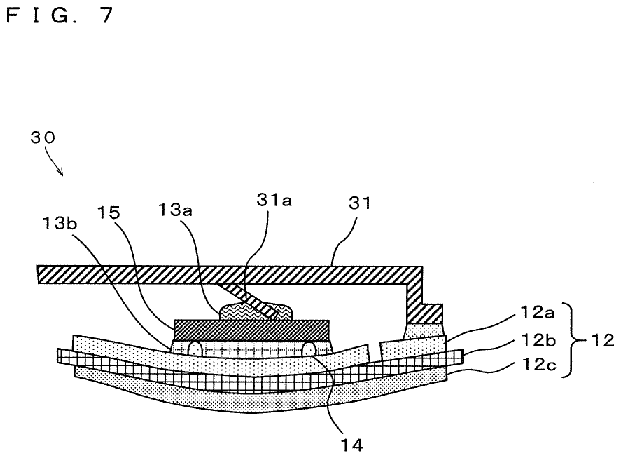

FIG. 5 is a schematic cross-sectional view of a semiconductor device 30 according to Embodiment 2. FIG. 6 is a schematic cross-sectional view when a lead electrode 41 is placed apart from the semiconductor element 15 in a semiconductor device 40 to which a conventional technology has been applied. FIG. 7 is a schematic cross-sectional view when a lead electrode 31 is placed apart from the semiconductor element 15 in the semiconductor device 30 according to Embodiment 2. FIGS. 6 and 7 are enlarged views centered around bonding portions of the semiconductor elements and the lead electrodes for the sake of simplicity. As illustrated in FIG. 5, the semiconductor device 30 according to Embodiment 2 differs from that according to Embodiment 1 in that a cantilevered plate 31a with flexibility comes in contact with the upper surface of the semiconductor element 15 and becomes deformed. The other structures of Embodiment 2 are identical to those of Embodiment 1. The cantilevered plate 31a that comes in contact with the upper surface of the semiconductor element 15 and becomes deformed can follow the upper surface of the semiconductor element 15, even when the distance between the semiconductor element 15 and the lead electrode 31 is changed into both directions of shortening and increasing the distance. The distance between the semiconductor element 15 and the lead electrode 31 may be changed due to, for example, shapes, dimensional tolerances, and heat deformation of the components included in the semiconductor device 30 in the direct bonding step. When a distance between the semiconductor element 15 and the lead electrode 41 in the semiconductor device 40 of the conventional technology is changed, the bonding layer 13a cannot follow the change in distance and may have malfunctions such as a bonding defect and fracture. In contrast, since the lead electrode 31 including the cantilevered plate 31a has flexibility in the semiconductor device 30 according to Embodiment 2, the cantilevered plate 31a can follow the change in distance between the semiconductor element 15 and the lead electrode 31. Thus, the semiconductor device 30 according to Embodiment 2 can reduce the malfunctions more than those by the conventional semiconductor devices.

FIGS. 6 and 7 illustrate more specific examples when the distance between the semiconductor element and the lead electrode is changed into the increasing direction. As illustrated in FIG. 6, when the distance between the semiconductor element 15 and the lead electrode 41 is increased in the semiconductor device 40 to which the conventional technology has been applied, a portion of the bonding layer 13a between the semiconductor element 15 and the lead electrode 41 becomes deformed in a direction in which the cross-sectional area of the portion decreases. The portion of the bonding layer 13a with the decreased cross-sectional area has higher current densities per unit area than that before deformation. When a large current flow through the portion with the decreased cross-sectional area, this may locally generate heat, and cause a failure. Consequently, the life of the semiconductor device may be shortened. In contrast, even when the distance between the semiconductor element 15 and the lead electrode 31 is increased in the semiconductor device 30 according to Embodiment 2, the cantilevered plate 31a becomes deformed in the direction of following the upper surface of the semiconductor element 15 as illustrated in FIG. 7. Deformation of the cantilevered plate 31a in the direction of following the upper surface of the semiconductor element 15 suppresses reduction of the cross-sectional area of the bonding layer 13a between the semiconductor element 15 and the lead electrode 31, and easily maintains the electrical connection therebetween more than those by the conventional semiconductor devices. This applies when a distance between a semiconductor element and a lead electrode is shortened. The stress between the semiconductor element 15 and the lead electrode 41 may damage the semiconductor device 40 of the conventional technology. In contrast, since the deformed cantilevered plate 31a with flexibility absorbs the stress between the semiconductor element 15 and the lead electrode 31 in the semiconductor device 30 according to Embodiment 2, the damage of the semiconductor device 30 can be prevented. In other words, the structure of the semiconductor device 30 including the cantilevered plate 31a with flexibility that comes in contact with the upper surface of the semiconductor element 15 and is deformed can prevent malfunctions between the semiconductor element 15 and the lead electrode 31, even when the distance between the semiconductor element 15 and the lead electrode 31 is changed into both directions of shortening and increasing the distance. When only the deformation in the direction of shortening the distance between the semiconductor element 15 and the lead electrode 31 is feared, the cantilevered plate 31a with flexibility need not always come in contact with the upper surface of the semiconductor element 15. This is because the cantilevered plate 31a has only to have a function of absorbing the stress caused by shortening the distance between the semiconductor element 15 and the lead electrode 31.

As described above, the semiconductor device 30 according to Embodiment 2 is characterized by the cantilevered plate 31a with flexibility in addition to the structure of the semiconductor device according to Embodiment 1.

This structure can produce the semiconductor device 30 which has a structure of directly bonding the lead electrode 31 to the semiconductor element 15 through the bonding layer 13a and which can absorb the stress caused by shortening the distance between the semiconductor element 15 and the lead electrode 31, in addition to the advantages of Embodiment 1.

Furthermore, the semiconductor device 30 according to Embodiment 2 is characterized in that the cantilevered plate 31a comes in contact with the semiconductor element 15 and becomes deformed, in addition to the structure of the semiconductor device according to Embodiment 1.

This structure can produce a semiconductor device which has a structure of directly bonding the lead electrode 31 to the semiconductor element 15 through the bonding layer 13a and which can prevent malfunctions between the semiconductor element 15 and the lead electrode 31 even when the distance between the semiconductor element 15 and the lead electrode 31 is changed into both directions of shortening and increasing the distance, in addition to the advantages of Embodiment 1. Although Embodiment 2 describes a case where the cantilevered plate 31a has flexibility, the cantilevered plate 31a has only to produce the advantage of absorbing the stress, and thus may be elastic.

### Embodiment 3

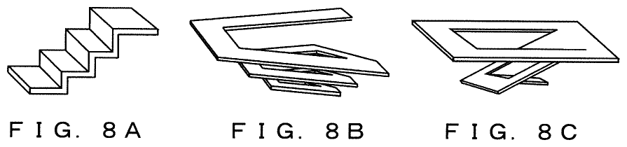

FIGS. 8A to 8C are perspective views illustrating example structures of cantilevered plates according to Embodiment 3. FIG. 8A illustrates the cantilevered plate having a staircase step structure going from one end connected to the main body plate to the other end toward a direction of a semiconductor element. FIG. 8B illustrates the cantilevered plate having a helical step structure going from one end connected to the main body plate to the other end toward a direction of a semiconductor element. FIG. 8C illustrates the cantilevered plate having a nested step structure going from one end connected to the main body plate to the other end toward a direction of a semiconductor element. As illustrated in FIGS. 8A to 8C, semiconductor devices according to Embodiment 3 differ from that according to Embodiment 1 in that each of the cantilevered plates has a step structure going from one end connected to the main body plate toward the direction of the semiconductor element. The other structures of Embodiment 3 are identical to those of Embodiment 1. With application of the cantilevered plates illustrated in FIGS. 8A to 8C, the cantilevered plates exposed from the bonding layers 13a vary in shape in a plan view, depending on an area of each of the bonding layers 13a which covers the cantilevered plate. In other words, checking the shape of the cantilevered plate exposed from the bonding layer 13a through a visual inspection can determine not only whether the bonding layer 13a has a predetermined thickness but also, for example, whether the bonding layer 13a falls within a tolerance of the predetermined thickness. This can increase the inspection accuracy of the thickness of the bonding layer 13a through a visual inspection similarly to Modification 2 of Embodiment 1, even without any scale line on the cantilevered plate. The cantilevered plates according to Embodiment 3 which are exposed from the bonding layers 3a not only continuously vary in shape in a plan view depending on the thickness of each of the bonding layers 13a, but also vary in shape in a plan view depending on whether the thickness of the bonding layer 13a exceeds the step structure of the cantilevered plate. Thus, an increase in the inspection accuracy is expected from not only a visual inspection but also an inspection through image recognition. The step structures each going from one end connected to the main body plate toward the direction of the semiconductor element are not limited to those in FIGS. 8A to 8C, but include any other shapes as long as the cantilevered plates exposed from the bonding layers 13a vary in shape in a plan view depending on the thickness of the bonding layer 13a.

As described above, the cantilevered plate has a step structure going from the one end toward the other end in the semiconductor device according to Embodiment 3, in addition to the structure of the semiconductor device according to Embodiment 1.

In this structure, the cantilevered plates exposed from the bonding layers vary in shape in a plan view depending on an area of each of the bonding layers which covers the cantilevered plate. Thus, it is possible to obtain a semiconductor device which has a structure of directly bonding a lead electrode to a semiconductor element through a bonding layer and in which whether the bonding layer has a predetermined thickness can be checked through a visual inspection with high accuracy without having a scale in the cantilevered plate, in addition to the advantages of Embodiment 1.

### Embodiment 4

Embodiment 4 is directed to a power conversion device on which any one of the semiconductor devices according to Embodiments 1 to 3 is mounted. The power conversion device may include not only one of the semiconductor devices according to Embodiments 1 to 3 but also a plurality of the semiconductor devices.

Thus, the power conversion device according to Embodiment 4 is a power conversion device on which any one of the semiconductor devices according to Embodiments 1 to 3 is mounted.

Since the power conversion device with such a structure can apply a semiconductor device which has a structure of directly bonding a lead electrode to a semiconductor element through a bonding layer and in which whether the bonding layer has a predetermined thickness can be checked through a visual inspection, an increase in the manufacturing cost with application of a non-destructive inspection can be suppressed. This can produce the power conversion device which includes a semiconductor device having a structure of directly bonding a lead electrode to a semiconductor element through a bonding layer and whose increase in manufacturing cost is suppressed.

The following will describe a summary of various aspects of the present disclosure as appendixes.

[Appendix 1]

A semiconductor device, comprising:
a semiconductor element mounted on an insulating substrate or a lead frame;
a bonding layer formed on the semiconductor element; and
a lead electrode including a main body plate electrically connected to an external electrode, and a cantilevered plate with one end being connected to the main body plate as a connection part, the cantilevered plate being cut from the main body plate,
wherein the cantilevered plate is bent in a direction of the semiconductor element with respect to the main body plate, and has an other end embedded in the bonding layer, and the bonding layer covers at least a part of an upper surface of the cantilevered plate.

[Appendix 2]

The semiconductor device according to appendix 1,
wherein the cantilevered plate includes a scale on the upper surface.

[Appendix 3]

The semiconductor device according to appendix 1 or 2,
wherein the cantilevered plate has a step structure going from the one end toward the other end.

[Appendix 4]

The semiconductor device according to any one of appendixes 1 to 3,
wherein the cantilevered plate has flexibility.

[Appendix 5]

The semiconductor device according to any one of appendixes 1 to 4.
wherein the cantilevered plate comes in in contact with the semiconductor element and becomes deformed.

[Appendix 6]

The semiconductor device according to any one of appendixes 1 to 5, further comprising:
a casing housing the semiconductor element; and
the external electrode a part of which is supported by the casing and which is electrically connected to the lead electrode.

[Appendix 7]

A method of manufacturing a semiconductor device, the method comprising:
a bonding layer formation step of forming a bonding layer on a semiconductor element;
a direct bonding step of embedding, into the bonding layer, an other end of a cantilevered plate with one end being connected to a main body plate of a lead electrode as a connection part to bond the other end to the semiconductor element, the other end being cut from the main body plate; and
a determination step of determining whether the bonding layer has a predetermined thickness through a visual inspection of the cantilevered plate exposed from the bonding layer.

[Appendix 8]

The method according to appendix 7,
wherein in the determination step, the visual inspection is performed through image recognition.

[Appendix 9]

A power conversion device on which the semiconductor device according to any one of appendixes 1 to 6 is mounted.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor element mounted on an insulating substrate or a lead frame;
a bonding layer formed on the semiconductor element; and
a lead electrode including a main body plate electrically connected to an external electrode, and a cantilevered plate with one end being connected to the main body plate as a connection part, the cantilevered plate being cut from the main body plate,
wherein the cantilevered plate is bent in a direction of the semiconductor element with respect to the main body plate, and has an other end embedded in the bonding layer, and the bonding layer covers at least a part of an upper surface of the cantilevered plate.

2. The semiconductor device according to claim 1,
wherein the cantilevered plate includes a scale on the upper surface.

3. The semiconductor device according to claim 1,
wherein the cantilevered plate has a step structure going from the one end toward the other end.

4. The semiconductor device according to claim 1,
wherein the cantilevered plate has flexibility.

5. The semiconductor device according to claim 4,
wherein the cantilevered plate comes in in contact with the semiconductor element and becomes deformed.

6. The semiconductor device according to claim 1, further comprising:
a casing housing the semiconductor element; and
the external electrode a part of which is supported by the casing and which is electrically connected to the lead electrode.

7. A method of manufacturing a semiconductor device, the method comprising:
a bonding layer formation step of forming a bonding layer on a semiconductor element;
a direct bonding step of embedding, into the bonding layer, an other end of a cantilevered plate with one end being connected to a main body plate of a lead electrode as a connection part to bond the other end to the semiconductor element, the other end being cut from the main body plate; and
a determination step of determining whether the bonding layer has a predetermined thickness through a visual inspection of the cantilevered plate exposed from the bonding layer.

8. The method according to claim 7,
wherein in the determination step, the visual inspection is performed through image recognition.

9. A power conversion device on which the semiconductor device according to claim 1 is mounted.
